(19) United States
(12) Patent Application Publication
(10) Pub. No.: US 2009/0071807 A1
(43) Pub. Date: Mar. 19, 2009

(54) MEMS SWITCH AND METHOD OF FABRICATING THE SAME

(75) Inventors: Shinichi KOMINATO, Tokyo (JP); Masao Segawa, Fujisawa (JP); Mariko Sugimoto, Yokohama (JP); Takeshi Miyagi, Fujisawa (JP); Michinobu Inoue, Yokohama (JP); Susumu Obata, Yokohama (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/187,734

(22) Filed: Aug. 7, 2008

(30) Foreign Application Priority Data
Aug. 8, 2007 (JP) 2007-206767

(51) Int. Cl. H01H 57/00; H01L 21/02

(52) U.S. Cl. 200/181; 438/50; 257/E21.002

(57) ABSTRACT

A MEMS switch includes a field generator which generates an electric field in a predetermined space, a beam located in the space and made of an electrically conductive material, the beam being flexed downward when subjected to an electrostatic force due to the electric field, the beam being deformed so as to return upward by an elastic restoring force upon extinction of the electrostatic force, a signal line electrically connected to the beam when the beam is flexed downward, and a protective cap covering the field generator, the beam, and the signal line, thereby sealing the field generator, the beam, and the signal line.

### CROSS-REFERENCE TO RELATED APPLICATIONS

This application is based on and claims the benefit of priority from the prior Japanese Patent Application No. 2007-206767, filed on Aug. 8, 2007, the entire contents of which are incorporated herein by reference.

### BACKGROUND OF THE INVENTION

1. Field of the Invention

The present invention relates to a micro electromechanical system (MEMS) switch which is manufactured by use of a micromachining technique and provided with a mechanically operable switch mechanism and a method of fabricating the same.

2. Description of the Related Art

Many electronic systems used in a high frequency band (RF band) have recently been further reduced in size and weight and further improved in performance. Semiconductor switches such as field-effect transistors (FETs) and PIN diodes have conventionally been used. However, the semiconductor switches have a problem that these switches necessitate a measurable amount of power. The semiconductor switches further necessitate improvements in high frequency characteristics.

In view of the foregoing problem, researches have recently been made to fabricate mechanically operable ultraminiature high-frequency MEMS switches by using a semiconductor microfabrication technique or a micromachining technique which is an extended version of the semiconductor microfabrication technique and can realize fabrication of miniature three-dimensional structures and movable mechanisms. Since the MEMS switches of the above-described type have a low insertion loss and high insulating performance, these MEMS switches can overcome shortcomings of the semiconductor switch.

An electrostatic force is used in a method of driving the foregoing MEMS switch. In this method, an electrostatic force acting between two opposite electrodes is used to turn on and off a switch. The method is advantageous in a simple structure and a simple fabrication process. As an example of such a MEMS switch, U.S. Pat. No. 6,440,767 to Robert Y. Loo et al. discloses a MEMS switch structure and a fabrication method.

Furthermore, Japanese Patent Application Publication No. JP-A-2001-52587 discloses an arrangement that a moving contact of a switch is kept in contact with a contact grounded at turnoff time, whereby a desired insulating characteristic is maintained. On the other hand, pointing out a defect that the grounded contact would be adherent when the moving contact is arranged to come into contact with the grounded contact, Japanese Patent Application Publication No. JP-A-2003-242873 suggests an arrangement to overcome the defect.

In the aforesaid Publication No. JP-A-2003-242873, a micro-relay is arranged so as to prevent adhesion of the contact by an elastic restoring force and an electrostatic force, whereby insulation properties and reliability can be improved. In this arrangement, however, the MEMS structure or the periphery of the contact remains exposed. As a result, dust and/or water adheres to the MEMS structure, reducing reliability and yield of the MEMS switch.

### SUMMARY OF THE INVENTION

Therefore, an object of the present invention is to provide a MEMS switch which can prevent dust and/or water from adhering to the MEMS structure and can improve the reliability and yield and a method of fabricating the same.

One aspect of the present invention provides a MEMS switch comprising a field generator which generates an electric field in a predetermined space, a beam provided in the space and made of an electrically conductive material, the beam being flexed downward when subjected to an electrostatic force due to the electric field, the beam being deformed so as to return upward by an elastic restoring force upon extinction of the electrostatic force, a signal line electrically connected to the beam when the beam is flexed downward, and a protective cap covering the field generator, the beam, and the signal line, thereby sealing the field generator, the beam, and the signal line.

The protective cap is provided in the above-described MEMS switch for covering the field generator, the beam, and the signal line, thereby sealing the field generator, the beam, and the signal line. Consequently, the MEMS switch can prevent dust and/or water from adhering to the MEMS switch structure and can accordingly improve the reliability and yield.

Another aspect of the invention provides a method of fabricating a MEMS switch, comprising forming a signal line and an electrostatic electrode on an insulated substrate, forming an insulating film on the electrostatic electrode, forming a first sacrificial layer on the insulated substrate, forming a beam conductor film on the first sacrificial layer, forming a beam contact electrode on the conductor film, forming a second sacrificial layer on the conductor film, forming a beam on the second sacrificial layer, forming a sacrificial layer removal opening in the beam, removing the first and second sacrificial layers, and closing the opening.

### BRIEF DESCRIPTION OF THE DRAWINGS

Other objects, features and advantages of the present invention will become clear upon reviewing the following description of one embodiment with reference to the accompanying drawings, in which:

FIG. 1 is a longitudinal section of a MEMS switch showing a first embodiment of the present invention;

FIG. 2 is a plan view of the MEMS switch;

FIGS. 3A to 3E are views showing sequential steps of a fabrication process of the MEMS switch;

FIGS. 4A to 4E are views showing other sequential steps of the fabrication process of the MEMS switch;

FIGS. 5A to 5C are views showing further other sequential steps of the fabrication process of the MEMS switch;

FIGS. 6A to 6C are views showing still further other sequential steps of the fabrication process of the MEMS switch;

FIG. 7 is a plan view of a silicon substrate in the state as shown in FIG. 3B;

FIG. 8 is a plan view of the silicon substrate in the state as shown in FIG. 3D;

FIG. 9 is a plan view of the silicon substrate in the state as shown in FIG. 3E;

FIG. 10 is a plan view of the silicon substrate in the state as shown in FIG. 4A;

FIG. 11 is a plan view of the silicon substrate in the state as shown in FIG. 4B;

FIG. 12 is a plan view of the silicon substrate in the state as shown in FIG. 4D;

FIG. 13 is a plan view of the silicon substrate in the state as shown in FIG. 4E;

FIG. 14 is a plan view of the silicon substrate in the state as shown in FIG. 5A;

FIG. 15 is a plan view of the silicon substrate in the state as shown in FIG. 5B;

FIG. 16 is a plan view of the silicon substrate in the state as shown in FIG. 5C;

FIG. 17 is a plan view of the silicon substrate in the state as shown in FIG. 5D;

FIG. 18 is a plan view of the silicon substrate in the state as shown in FIG. 6A;

FIG. 19 is a plan view of the silicon substrate in the state as shown in FIG. 6B; and

FIG. 20 is a view similar to FIG. 1, showing a second embodiment of the invention.

### DETAILED DESCRIPTION OF THE INVENTION

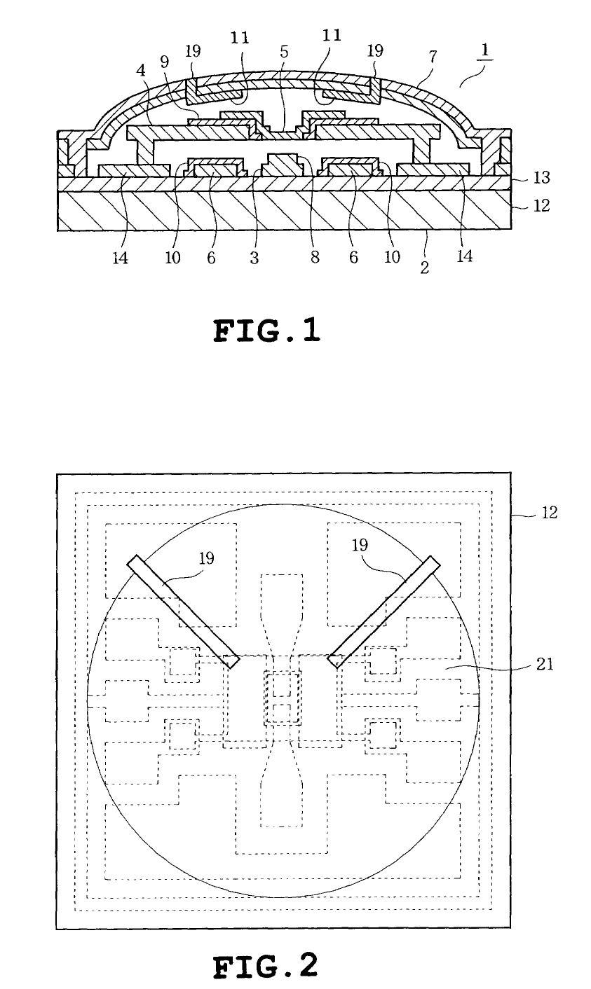

A first embodiment of the present invention will be described with reference to FIGS. 1 to 19 of the accompanying drawings. FIG. 1 is a longitudinal section of a MEMS switch 1 of the first embodiment. FIG. 2 is a plan view of the MEMS switch 1. The MEMS switch 1 includes an insulated substrate 2, a signal line 3 provided on the substrate 2, beams 4 provided across the signal line 3, a beam electrode 5 provided on the beams 4, electrostatic electrodes 6 provided on the substrate 2, and a protective cap 7 provided on the substrate 2.

The signal line 3 is designed so that a high frequency signal passes therethrough. The signal line 3 is divided as shown in FIG. 8. Two contact electrodes 8 (see FIG. 1) are provided on the divided signal line 3. When the beams 4 are deformed downward or more specifically, flexed downward, the beam electrode 5 is brought into contact with the contact electrodes 8 such that the signal line 3 is electrically conducted, that is, the MEMS switch 1 is turned on. Furthermore, when the beams 4 are returned upward, or more specifically, deformed upward, the beam electrode 5 is caused to depart from the contact electrodes 8 thereby to cut off the signal line 3, that is, to turn off the MEMS switch 1.

Each beam 4 is made of an electrically conductive material. Each electrostatic electrode 6 is provided for generating an electrostatic force for deforming the corresponding beam 4 and thus constitutes a field generator which generates an electric field in a predetermined space, namely, a space defined between each beam 4 and the corresponding electrostatic electrode 6. When DC voltage is applied between each electrostatic electrode 6 and the corresponding beam 4, the electrostatic force acts on the beam 4, thereby flexing the beam 4 downward or in such a direction that the beam 4 comes close to the contact electrodes 8 of the signal line 3. Each insulator film 9 is provided between the beam electrode 5 and each beam 4 in order to electrically insulate the beam electrode 5 and each beam 4. Furthermore, two insulator films 10 are provided on upper surfaces of the electrostatic electrodes 6 respectively.

Two cap-integral electrostatic electrodes 11 are formed integrally on an inner surface of the protective cap 7 as shown in FIG. 1. The cap-integral electrostatic electrodes 11 constitute a field generator which generates an electric field in a predetermined space, namely, a space defined between each beam 4 and the electrostatic electrode 6. In this configuration, when application of DC voltage is stopped between each electrostatic electrode 6 and the corresponding beam 4, each beam 4 is returned to the former state by an elastic restoring force upon extinction of the electrostatic force upward or in such a direction that each beam 4 is departed from the corresponding contact electrode 8. In this case, when DC voltage is applied between each cap-integral electrostatic electrode 11 and the corresponding beam 4, an electrostatic force acts on each beam 4, whereupon each beam 4 tends to be easily returned upward or in such a direction that each beam 4 is departed from the corresponding contact electrode 8.

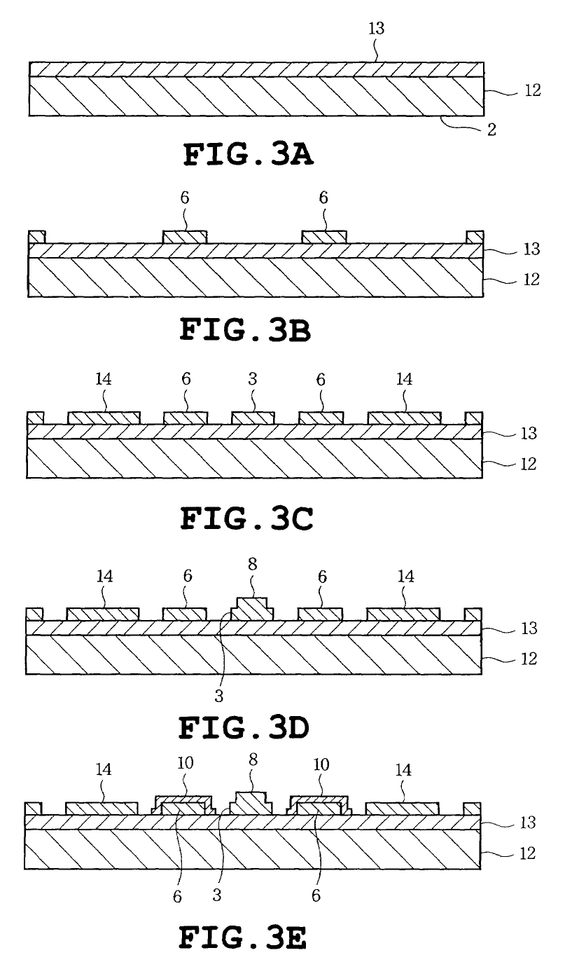

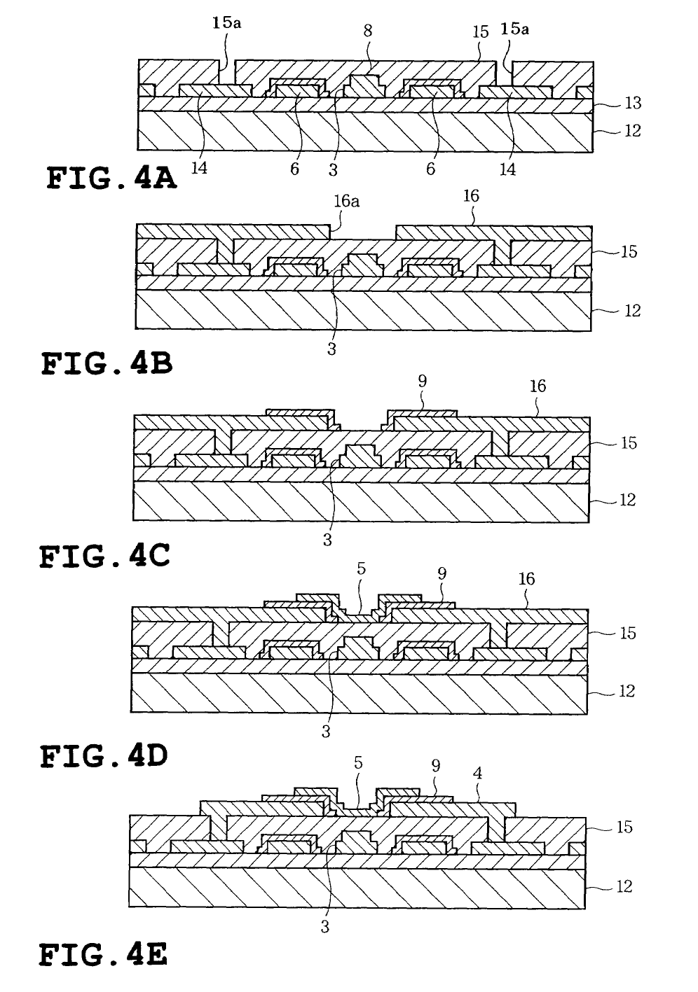

A fabrication process of the above-configured MEMS switch 1 will now be described with reference to FIGS. 3A to 19. Firstly, an insulating film 13 such as SiO₂ film is formed on a surface of the silicon substrate 12 having a previously set thickness of about 500 μm by a thermal oxidation treatment as shown in FIG. 3A. It is desirable that the thickness of the insulating film 13 should range from 500 nm to several μm for securement of electrical insulation. The silicon substrate 12 formed with the insulating film 13 serves as the insulated substrate 2.

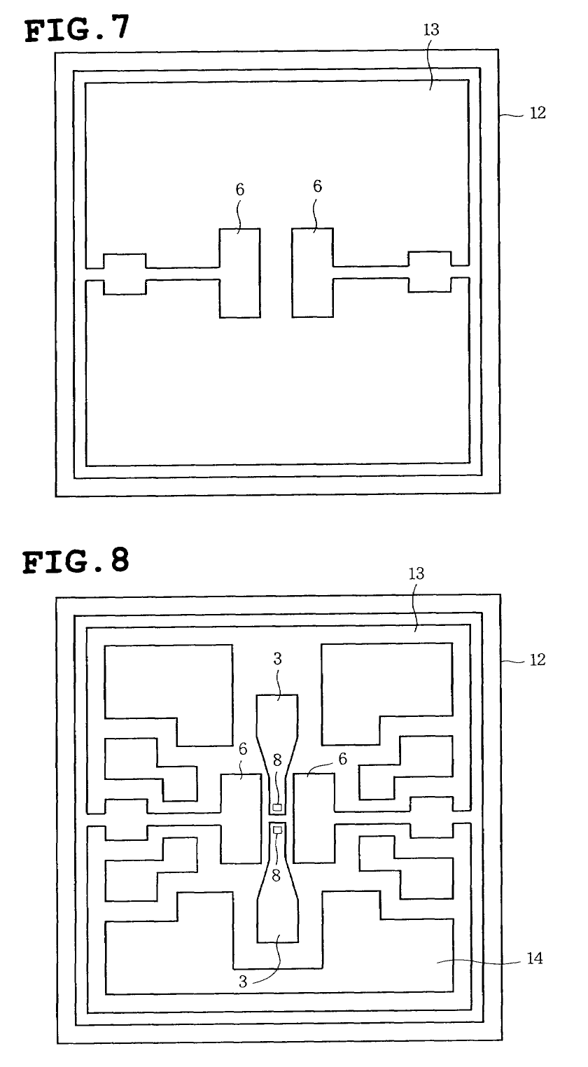

Subsequently, a film of conductor such as Cu, Al or Au is formed on the insulating film 13 by a sputtering or vapor deposition process as shown in FIG. 3B. The conductor film is then processed by a photolithography process thereby to be formed into the signal line 3, the electrostatic electrodes 6 and GNDs 14 as shown in FIG. 3C. Each of the signal line 3, the electrostatic electrodes 6 and GNDs 14 has a previously set thickness ranging from 1 μm to several μm, for example. FIG. 3B shows the electrostatic electrodes 6 and FIG. 3C shows the signal line 3 and the GNDs 14 as well as the electrostatic electrodes 6. FIG. 7 is a plan view of the silicon substrate 12 in the state as shown in FIG. 3B.

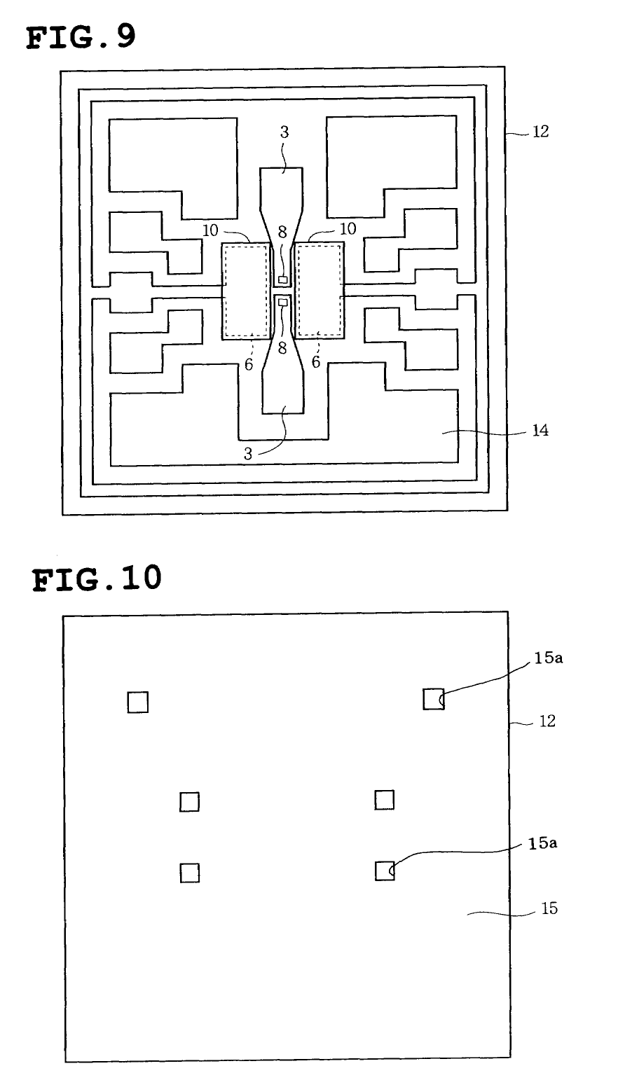

A contact electrode 8 is formed on the signal line 3 as shown in FIG. 3D. The signal-line side contact electrode 8 is made of a noble metal such as Au or Pt or an alloy of Au and Pt. The contact electrode 8 has a previously set thickness ranging from several hundreds nm to 1 μm. FIG. 8 is a plan view of the silicon substrate 12 in the state as shown in FIG. 3D. Furthermore, insulator films 10 of SiO₂ are formed on the electrostatic electrodes 6 respectively as shown in FIG. 3E. Each insulator film 10 has a previously set thickness ranging from 150 nm to 300 nm. FIG. 9 is a plan view of the silicon substrate 12 in the state as shown in FIG. 3E.

When the forming of a lower layer part of the MEMS switch 1 has been completed as described above, the fabrication process then advances to a step of forming a hollow structure of the beam 4 which is one of the features of the MEMS switch 1. Firstly, a first sacrificial layer 15 is formed by a coating process such as a spin coating with use of an organic material or spray coating as shown in FIG. 4A. Alternatively, a polysillicon film or the like may be formed by sputtering or a chemical vapor deposition (CVD) process. The first sacrificial layer 15 has a desirable thickness of about 1 μm in a part thereof located near the contact electrode 8. Openings or holes 15a are formed through the first sacrificial layer 15 in order that the beams 4 may be connected therethrough to the GNDs 14 respectively. FIG. 10 is a plan view of the silicon substrate 12 in the state as shown in FIG. 4A.

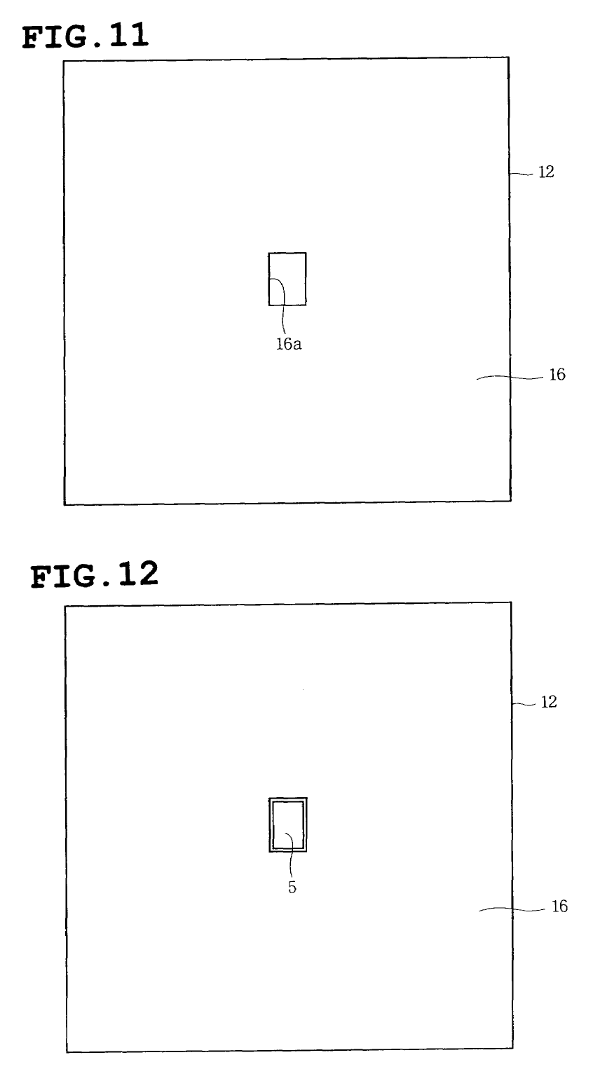

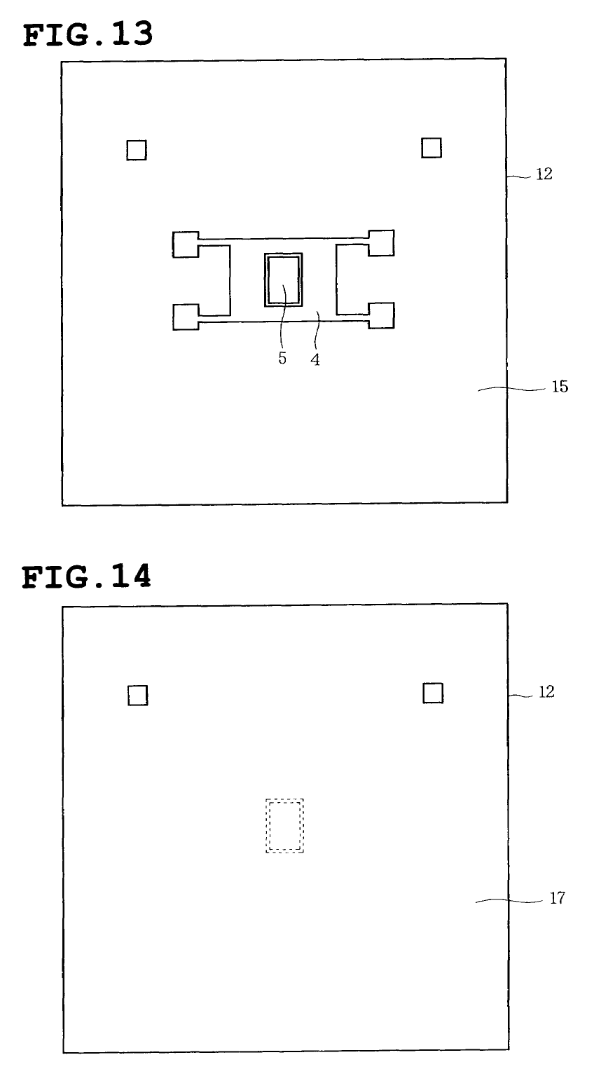

Subsequently, a conductor film 16 of Al or the like (conductive material) for the beams 4 is formed as shown in FIG. 4B. An opening 16a for the beam electrode 5 is formed through the conductive film 16. The conductor film 16 has a desirable thickness ranging from 1 to several μm. FIG. 11 is a plan view of the silicon substrate 12 in the state as shown in FIG. 4B. Subsequently, as shown in FIG. 4C, an insulator film 9 of SiO₂ or the like is formed on a part of the upper surface of the conductor film 16 and an inner peripheral surface and a part of the upper surface of the first sacrificial layer 15. The insulator film 9 has a previously set thickness ranging from 150 to 300 nm. A beam electrode 5 for the beam 4 side is formed on a part of the insulator film 9 and a part of the first sacrificial layer 15 corresponding to the opening 16a as shown in FIG. 4D. The beam electrode 5 is made of a noble metal such as Au or Pt or an alloy of Au and Pt. The beam electrode 5 has a previously thickness ranging from several hundreds nm to 1 μm. FIG. 12 is a plan view of the silicon substrate 12 in the state as shown in FIG. 4D. Subsequently, the conductor film 16 for the beam 4 is patterned by the photolithography process thereby to be formed into the beam 4. FIG. 13 is a plan view of the silicon substrate 12 in the state as shown in FIG. 4E.

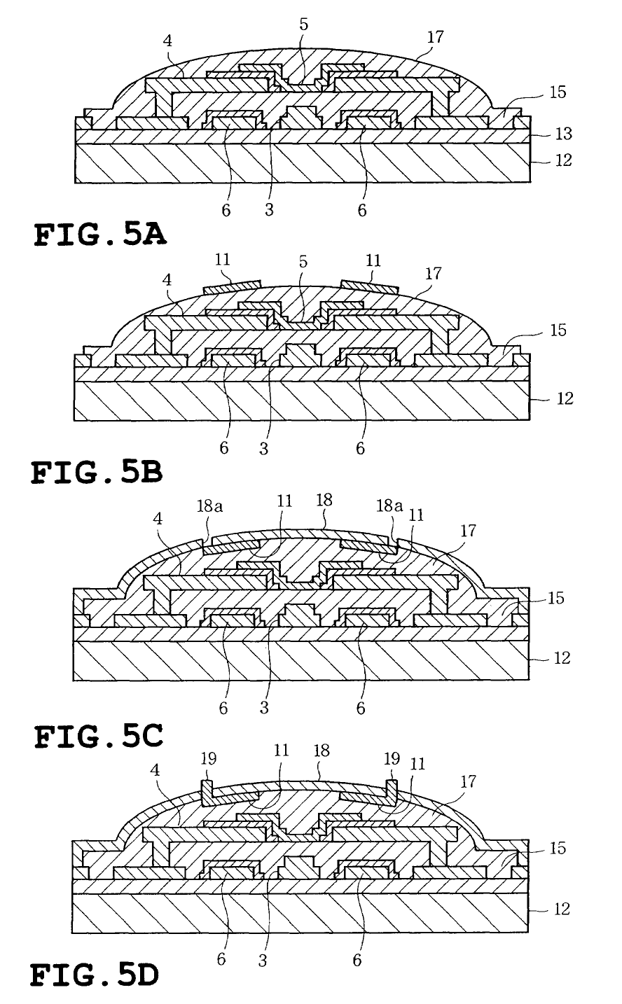

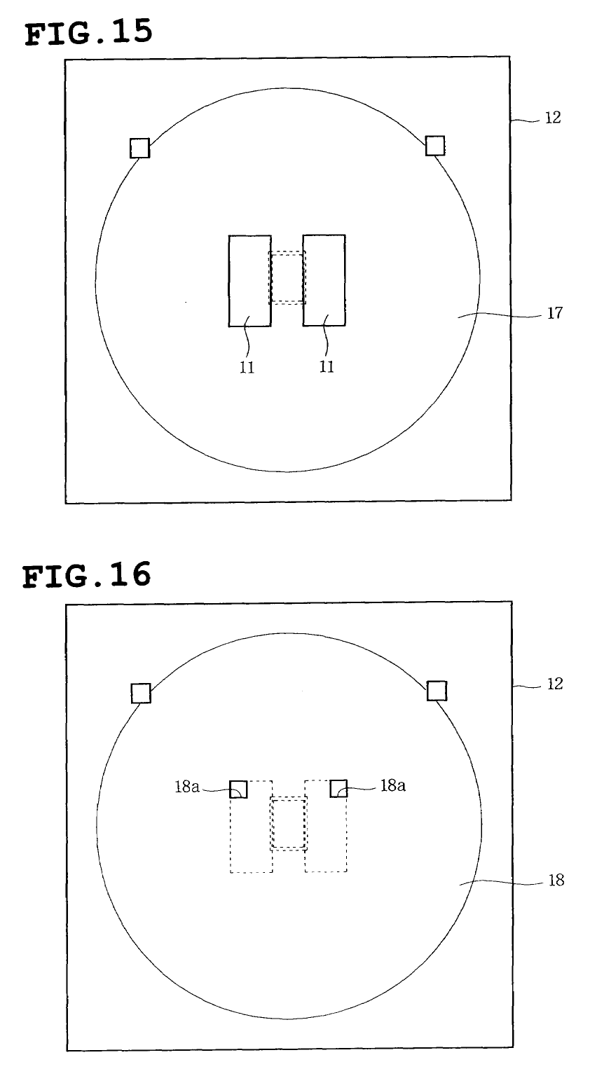

Subsequently, as shown in FIG. 5A, a second sacrificial layer 17 for forming the protective cap 17 is formed by the coating process such as the spin coating with use of an organic material or spray coating in the same manner as the first sacrificial layer 15. Alternatively, a polysillicon film or the like may be formed by sputtering or a chemical vapor deposition (CVD) process. The second sacrificial layer 17 has a desirable thickness of about 5 μm from the upper surface of the substrate 12. FIG. 14 is a plan view of the silicon substrate in the state as shown in FIG. 5A. Subsequently, the cap-integral electrostatic electrodes 11 are formed on the second sacrificial layer 17 as shown in FIG. 5B. In this case, a film of conductor such as Cu, Al or Au is formed by a sputtering or vapor deposition process. The conductor film is then processed by a photolithography process thereby to be formed into the cap-integral electrostatic electrodes 11. FIG. 15 is a plan view of the silicon substrate 12 in the state as shown in FIG. 5B.

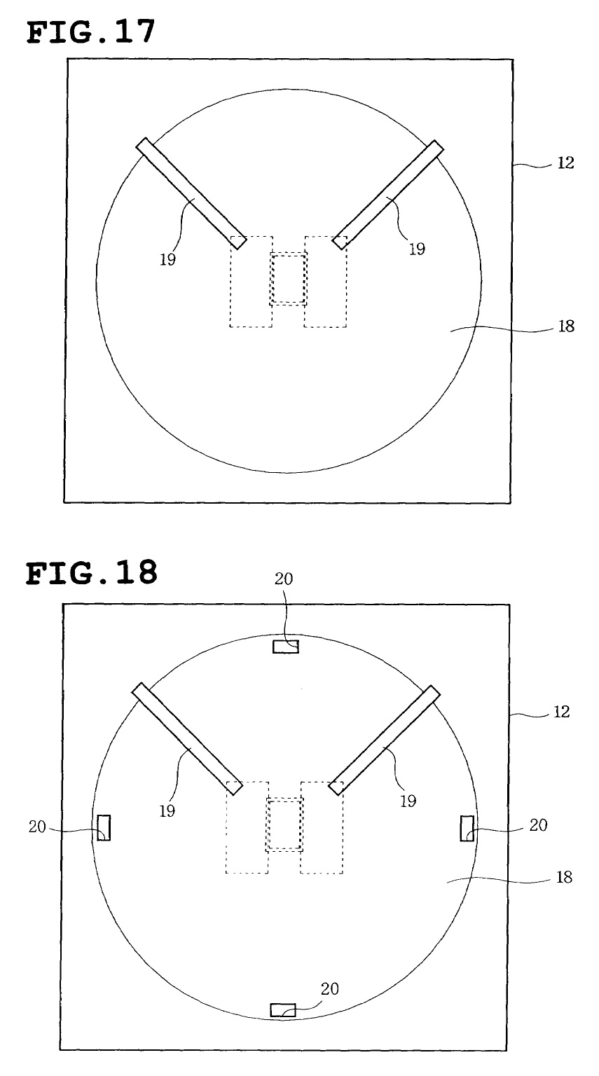

Subsequently, a film 18 for the protective cap 7 or cap film is formed as shown in FIG. 5C. The cap film 18 is made of SiO₂, SiN or the like. The cap film 18 has a previously set thickness ranging from 1 μm to 5 μm, for example. Subsequently, holes 18a for lead to respective electrodes are formed through the cap film 18. FIG. 16 is a plan view of the silicon substrate 12 in the state as shown in FIG. 5C. Subsequently, lead conductors 19 are formed so as to be connected to the electrodes 11 as shown in FIG. 5D. Each lead conductor 19 is made of Cu, Al, Au or the like and has a previously set thickness of about 1 μm. FIG. 17 is a plan view of the silicon substrate 12 in the state as shown in FIG. 5D.

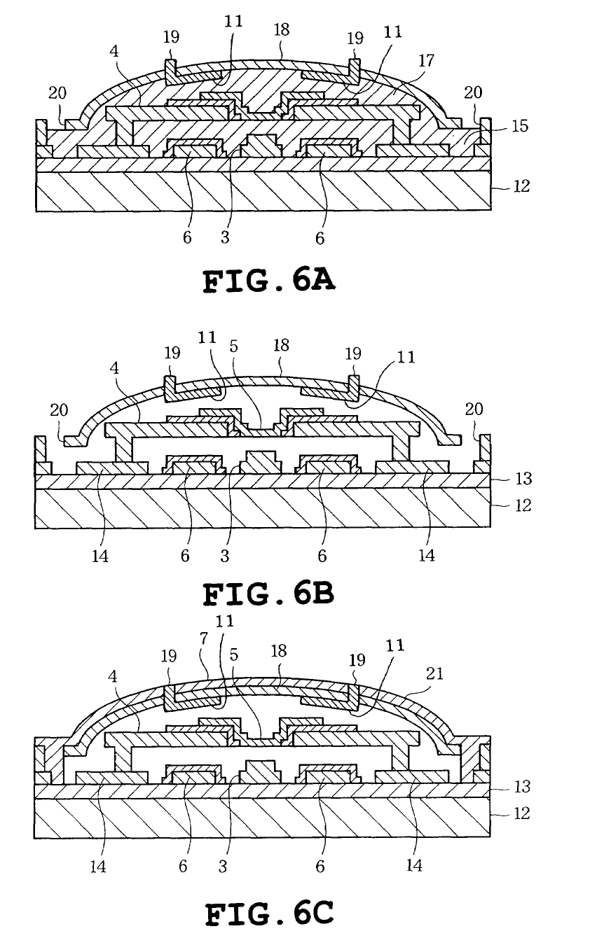

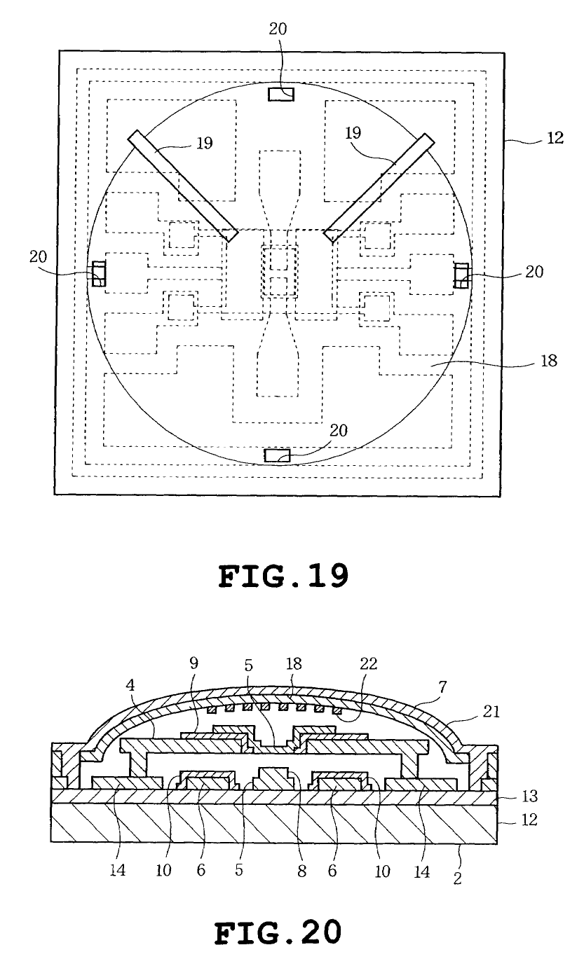

Subsequently, removing holes 20 for removing the first and second sacrificial layers 15 and 17 or sacrificial layer removing openings are formed through the cap 18 as shown in FIG. 6A. FIG. 18 is a plan view of the silicon substrate in the state as shown in FIG. 6A. Thereafter, the first and second sacrificial layers 15 and 17 are removed as shown in FIG. 6B. In this case, when the sacrificial layers 15 and 17 are made of an organic polyimide film or the like, an ashing device (not shown) is used to remove the sacrificial layers 15 and 17. When the sacrificial layers 15 and 17 are made of a polysillicon film or the like, a reactant gas such as hydrogen fluoride (HF) is used to remove the sacrificial layers 15 and 17. FIG. 19 is a plan view of the silicon substrate 12 in the state as shown in FIG. 6B. When a wet etching process is employed to remove the sacrificial layers 15 and 17, a hollow structure such as the beams 4, cap film 18 or the like would sometimes sticks to the substrate 12 (a sticking phenomenon). In view of the sticking, it is desirable to employ a dry etching process.

Subsequently, a film 21 for the protective cap 7 or a cover film is formed in order that the aforesaid removing holes 20 or the sacrificial layer removing openings may be closed, as shown in FIG. 6C. The cover film 21 and the cap film 18 constitute the protective cap 7. The cover film 21 is made of SiO₂, SiN or the like. It is desirable that the cover film 21 should have a thickness of approximately 5 μm. The MEMS switch 1 is completed when the cover cap 21 has been formed. FIG. 2 is a plan view of the silicon substrate 1 in the state as shown in FIG. 6C. Although the entire upper surface of the cap film 18 is covered with the cover film 21 in the foregoing embodiment, the cover film may be provided only in the periphery of each removing hole 20 so as to close each removing hole 20, instead.

According to the foregoing embodiment, the electrostatic electrodes 6 (electric field generator), beams 4 and signal line 3 are covered by the protective cap so as to be sealed. Consequently, the MEMS switch 1 can prevent dust and/or water from adhering to the MEMS switch structure and can accordingly improve the reliability and yield of the MEMS switch.

Furthermore, the cap-integral electrostatic electrodes 11 are provided on the inner peripheral surface of the protective cap 7 in the foregoing embodiment. Each beam 4 that is in a downwardly flexed state is caused to return upward by the elastic restoring force. For this purpose, voltage is applied between each cap-integral electrostatic electrode 11 and the corresponding beam 4, so that each beam 4 is caused to return upward by the electrostatic force due to the electric field from the cap-integral electrostatic electrode 11. Consequently, adhesion of contacts can further be prevented.

Furthermore, the protective cap 7 is provided for sealing the MEMS structure part thereby to protect the MEMS structure part, in the foregoing embodiment. Since the step of forming the protective cap 7 is incorporated in the semiconductor process or a process of fabricating a semiconductor device. Consequently, the fabrication process of the MEMS switch can be simplified and accordingly the fabrication cost can be reduced.

Although the cap-integral electrostatic electrodes 11 are provided on the inner peripheral surface of the protective cap 7 in the foregoing embodiment, the cap-integral electrostatic electrodes 11 may or may not be provided.

Although each beam 4 is made of the electrically conductive material in the foregoing embodiment, each beam 4 may be made of a material which is both an electrically conductive material and a soft magnetic material, such as FeSi, Ni or the like, instead.

FIG. 20 illustrates a second embodiment of the invention. Identical or similar parts are labeled by the same reference symbols in the second embodiment as those in the first embodiment. In the second embodiment, each beam 4 is made of a material which is both an electrically conductive material and a soft magnetic material, such as FeSi, Ni or the like. Furthermore, a cap-integral thin-film coil 22 is provided on the inner peripheral surface of the protective cap 7, instead of the cap-integral electrostatic electrodes 11. The cap-integral thin-film coil 22 constitutes a field generator which generates an electric field in a predetermined space, namely, a space defined between each beam 4 and the protective cap 7.

In the above-described configuration, when each beam 4 that is in a downwardly flexed state is caused to return upward by the elastic restoring force, the cap-integral thin-film coil 22 is energized so that each beam 4 is caused to return upward by a magnetic force from the cap-integral thin-film coil 22.

The other configuration of the second embodiment is generally the same as of the first embodiment. Consequently, the second embodiment can achieve substantially the same effect as the first embodiment. Particularly in the second embodiment, the cap-integral thin-film coil 22 is provided on the inner peripheral surface of the protective cap 7. Consequently, each beam 4 made of the soft magnetic material can be deformed so as to return upward when each beam 4 that is in the downwardly flexed state is to be deformed so as to return upward by the elastic restoring force.

The foregoing description and drawings are merely illustrative of the principles of the present invention and are not to be construed in a limiting sense. Various changes and modifications will become apparent to those of ordinary skill in the art. All such changes and modifications are seen to fall within the scope of the invention as defined by the appended claims.

What is claimed is:

1. A MEMS switch comprising:
a field generator which generates an electric field in a predetermined space;
a beam provided in the space and made of an electrically conductive material, the beam being flexed downward when subjected to an electrostatic force due to the electric field, the beam being deformed so as to return upward by an elastic restoring force upon extinction of the electrostatic force;
a signal line electrically connected to the beam when the beam is flexed downward; and
a protective cap covering the field generator, the beam, and the signal line, thereby sealing the field generator, the beam, and the signal line.

2. The MEMS switch according to claim 1, wherein the beam is made of a soft magnetic material.

3. The MEMS switch according to claim 1, further comprising another field generator provided on the protective cap for generating an electric field in the space, wherein the beam is caused to return upward by the electrostatic force from the cap when the beam that is in the downwardly flexed state is to be deformed so as to return upward by the elastic restoring force.

4. The MEMS switch according to claim 2, further comprising another field generator provided on the protective cap for generating an electric field in the space, wherein the beam is caused to return upward by the electrostatic force from the cap when the beam that is in the downwardly flexed state is to be deformed so as to return upward by the elastic restoring force.

5. The MEMS switch according to claim 2, further comprising another field generator provided on the protective cap for generating an electric field in the space, wherein the beam is caused to return upward by the magnetic force from the cap when the beam that is in the downwardly flexed state is to be deformed so as to return upward by the elastic restoring force.

6. A method of fabricating a MEMS switch, comprising:
forming a signal line and an electrostatic electrode on an insulated substrate;
forming an insulating film on the electrostatic electrode;
forming a first sacrificial layer on the insulated substrate;
forming a beam conductor film on the first sacrificial layer;
forming a beam contact electrode on the conductor film;
forming a second sacrificial layer on the conductor film;
forming a beam on the second sacrificial layer;
forming a sacrificial layer removal opening in the beam;
removing the first and second sacrificial layers; and
closing the opening.

7. The method according to claim 6, further comprising forming an electrostatic electrode on the second sacrificial layer, wherein the beam is formed on the second sacrificial layer and the electrostatic electrode in the beam forming step.

8. The method according to claim 6, wherein the conductor film is made of a soft magnetic material, the method further comprising forming a thin film coil on the second sacrificial layer, wherein the beam is formed on the second sacrificial layer and the thin film coil in the beam forming step.
